(19) United States
(12) Patent Application Publication
(10) Pub. No.: US 2007/0269595 A1
(43) Pub. Date: Nov. 22, 2007

(54) Method for preventing metal leaching from copper and its alloys

(75) Inventors: Kari Harkonen, Kauniainen (FI); Olli Jylha, Espoo (FI)

Correspondence Address: BUCHANAN, INGERSOLL & ROONEY PC, POST OFFICE BOX 1404, ALEXANDRIA, VA, 22313-1404, US

(73) Assignee: PLANAR SYSTEM OY, Espoo (FI)

(21) Appl. No.: 11/604,279

(22) Filed: Nov. 27, 2006

Related U.S. Application Data
(60) Provisional application No. 60/739,931, filed on Nov. 28, 2005.

(51) Int. Cl. C23C 16/00; B05D 1/00

(52) U.S. Cl. 427/248.1; 427/258

(57) ABSTRACT

A method is provided for reducing or eliminating the leaching of metal from a metal surface comprising copper when a liquid comes in contact with the surface. Such unwanted leaching is effectively controlled by coating the metal surface at least partially with a film comprising titanium and oxygen (e.g., titanium oxide). In preferred embodiments the coating of the metal surface is achieved by chemical vapor deposition, metal organic vapor deposition, or by a sol-gel technique. The method is particularly useful when the metal surface is a plumbing component or an assembly of plumbing components and the liquid is water intended for human consumption.

The benefit of U.S. Provisional Application No. 60/739,931, filed Nov. 28, 2005 is claimed under 35 U.S.C. §119(e).

### TECHNICAL FIELD

The present invention relates to the prevention of the leaching of metals into water in contact with an object comprising copper. In particular, the invention relates to the prevention of the leaching of metals such as copper and lead from a plumbing component for potable water.

### BACKGROUND OF THE INVENTION

A problem occurring with plumbing fixtures is the leaching of various metals from the material making up the surfaces contacting the water. Plumbing fixtures are generally manufactured from copper-containing alloys, containing for example zinc or lead in order to improve the workability and machinability of the metal. Also, solders and fluxes used in the manufacture of plumbing fixtures usually contain various metals, which are not fully inert in an aqueous environment. Thus, faucets, valves and related products for delivering potable water may have a tendency to release small amounts of metal, which are undesirable in water intended for consumption due to their toxic or potentially toxic properties. The amount of released metals is influenced by a number of factors, including pH and dissolved solids, and it may vary with time, often being relatively high after the installation of the fitting. Testing procedures and maximum metal release concentrations for various categories of plumbing fixtures, fittings and pipes for the US market are specified in ANSI/NSF Standard 61.

Attempts to reduce or eliminate this problem have involved various treatments and coatings of the inner surfaces of the fixtures. In German OS 35 15 718, a water faucet is disclosed having a plastic coated boring making up the water conduit, while the faucet body is manufactured from a zinc alloy which is less expensive than brass. Tin plating of the wetted surfaces of a fitting made of copper alloy is described in, for example, German patent 14 192 and U.S. Pat. No. 5,876,017. In U.S. Pat. No. 5,958,257, a treatment is disclosed in which a brass component is treated with a caustic solution, leached, and treated with carboxylic acid in order to remove leachable lead. According to U.S. Pat. No. 6,461,534, the treatment sequence is first acid, then alkali. In U.S. Pat. No. 6,656,294, a method is disclosed in which the surface is alkali treated and subsequently a chromate plating is applied. According to European patent application 1 548 155 A, a dilute solution of nitric and hydrochloric acids is used to remove lead and nickel and to passivate the copper surface.

The multilayer coating of copper-alloy objects, such as faucets, for decorative purposes and to improve wear resistance, is disclosed in e.g. U.S. Pat. No. 5,879,532, U.S. Pat. No. 6,221,231 and U.S. Pat. No. 6,399,219. Organic polymers, metals and their compounds are used; coating techniques include electroplating, dipping and various vapor deposition methods. However, these methods do not eliminate the leaching of unwanted material from the coated objects.

### SUMMARY OF THE INVENTION

According to one aspect of the present invention, a method is provided for reducing or eliminating the leaching of undesirable metals by forming an inert, at least partial film comprising titanium and oxygen on copper or copper-alloy surfaces. Particularly, the surfaces are those of plumbing components such as faucets, valve components and the like, and more particularly those surfaces that are in water contact during use. Thus, the surfaces coated in accordance with the present invention are in particular the inner surfaces of a hollow object. The object in question may be a single component, e.g. a plumbing component, or an assembly of several such components.

According to a further aspect of the invention, plumbing components having an inert, at least partial film on copper or copper-alloy surfaces are provided.

The expressions “at least partial film” and “coated at least partially” in this context imply, that the film need not cover the copper or copper alloy surface completely. Discontinuities in the film may be due to, e.g., cracking caused by stretching or bending of the substrate material; to grain boundaries particularly in a crystalline material; to insufficient cleaning prior to the coating process; impurities or particles on the substrate surface; or to physical damage. Sections of the surface may also be left uncoated e.g. for technical reasons relating to the joining of parts.

Metal leaching is reduced considerably by using at least a partial film according to this invention, even if the film coating includes discontinuities as described above. Preferably, however, at least 30% of the surface is coated by a film according to this invention. According to a preferable embodiment of the present invention, the surface is completely covered by a film coating according to the invention. “Completely” should be taken as free from defects from a practical point of view.

A final film coating may include several layers with different functionality. Typical functional layers are primer layers, barrier layers and protective layers. The film coating formed according to the invention includes at least one layer comprising titanium and oxygen. In particular, this layer comprises titanium oxide. For the purpose of this text, “oxide” refers to all oxides (for example, titanium oxide, aluminium oxide, tantalum oxide) of various chemical composition, phase and crystalline structure. Correspondingly, where a stoichiometric chemical formula is used, as is common practice in the field, this does not necessarily imply that the layer in question has the corresponding absolute stoichiometric composition. Titanium oxide is commonly referred to as titanium dioxide, TiO₂. Preferably, the film is formed by means of atomic layer deposition (ALD), also called atomic layer epitaxy (ALE). This method is particularly suitable for the relevant purpose, as it makes possible the uniform and reliable coating of rough or irregular surfaces, especially the inner surfaces of hollow or tube-shaped objects, to yield a tight, pinhole-free layer. A representative description of this technology may be found in e.g., Atomic Layer Epitaxy, Suntola, T. and Simpson, M., eds., Blackie and Son Ltd., Glasgow, 1990. A detailed description of TiO₂ deposition using this technology may be found in the thesis of Mikko Ritala, Atomic Layer Epitaxy growth of titanium, zirconium and hafnium dioxide thin films, Annales Academia Scientiarum Fennica, Series A, II. Chemica 257, Helsinki 1994. Examples of patents relating to ALD are U.S. Pat. No. 4,058,430, U.S. Pat. No. 4,389,973, U.S. Pat. No. 4,413,022, U.S. Pat. No. 6,941,963, U.S. Pat. No. 6,907,897 U.S. Pat. No. 6,936,086 and FI 84980.

Other possible techniques include Chemical Vapor Deposition (CVD), Metal Organic Vapor Deposition (MOCVD) and sol-gel-type processes. Descriptions can be found in, e.g., Bradley, D. C., Mehrotha, R. C., Rothwell, I. P. and Singh, A., Alkoxo and Aryloxo Derivatives of Metals, Academic Press 2001.

The finished film may comprise several materials, for example silicon, in addition to titanium and oxygen. Contaminants, such as H, C, N or Cl from the manufacturing processes of the raw materials of the reagents used in the coating process, are typically present in a total amount below 20% by weight. The amount of impurities, e.g. a weight percentage of above 0.1 of Cl or H in the process for depositing titanium oxide may have a positive influence on the barrier properties of the resulting layer, e.g. by having an effect on the degree of amorphousness. Such impurities may be included in the precursors.

Titanium oxide is well suited for the coating of plumbing components, as titanium oxide is chemically stable in all relevant aqueous environments. It is widely used and considered physiologically safe. Further, there are a number of useful depositing methods for this material.

Amorphous, crystalline (e.g. anatase, brookite or rutile) or polycrystalline titanium oxide or mixtures of these are all preferred materials according to the present invention. An amorphous titanium oxide layer is particularly advantageous, as interfaces (e.g. grain boundaries) occurring in a crystalline structure may act as a channel for metals prone to leach through. For the formation of an amorphous layer, low temperatures are preferable. To keep production costs at a reasonable level, no excessive layer thicknesses should be used. Preferably, the total thickness of the coating according to the invention (that is, excluding any additional functional layers e.g. primer and protective layers) is less than 10 000 nm; more preferable, in the range 3-1000 nm; most preferable in the range 30-100 mn. A coating process according to the invention is preferably carried out at a temperature in the range 10° C.-500° C.; preferably 20° C.-150° C.; more preferably 60° C.-140° C. The expression substrate for the purposes of this text refers to the surface being coated, and the process temperature referred to is the substrate temperature. Inert carrier gases include nitrogen, argon, carbon dioxide and dry air. The process may be carried out at pressures up to atmospheric pressure, but reduced pressure levels are advantageous. Preferably, the process pressure is in the range 10-7000 Pa, more preferably in the range 25-3000 Pa. In a preferred method according to the invention, the gaseous precursors and purge gases flow through the same conduit that carries water during the final use of the object being coated.

### BRIEF DESCRIPTION OF THE DRAWINGS

FIG. 1 shows a section of a surface coated according to the invention,

FIG. 2 shows a corresponding section of an object having a rough surface,

FIG. 3 shows a section of a surface coated according to the invention and having an additional protective layer,

FIG. 4 shows a section of a surface coated according to the invention and having a primer layer between the substrate and the coating,

FIGS. 5 to 7 show examples of surfaces partly coated according to the invention,

FIG. 8 is a schematic representation of objects being coated in a coating chamber,

FIG. 9 is a representation of an object being internally coated, and

FIG. 10 shows an example of the simultaneous coating of several objects.

### DETAILED DISCLOSURE

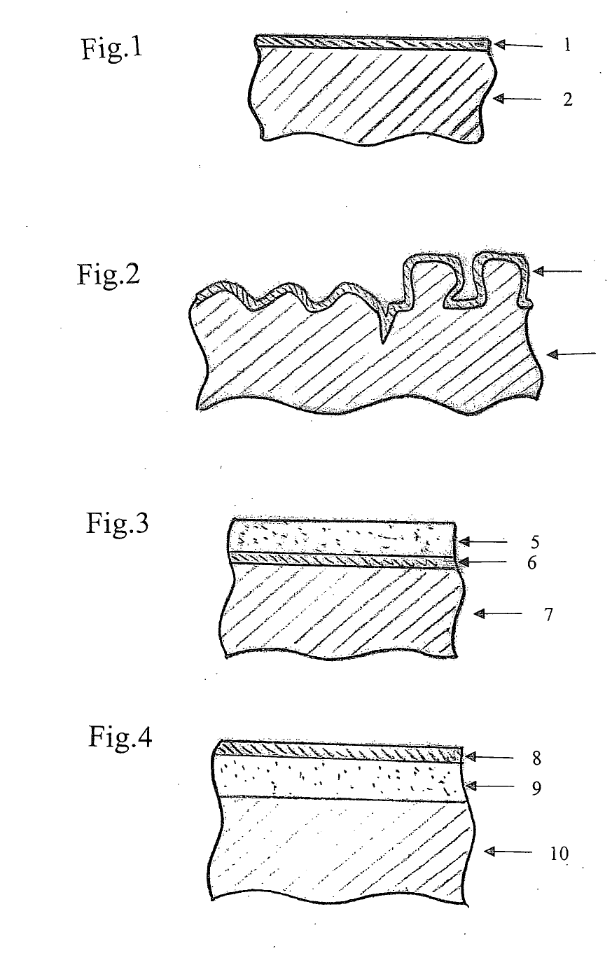

FIG. 1 shows a section through the wall of a coated object, e.g. a longitudinal section of the inner wall of a water faucet. The film coating 1 comprises at least titanium and oxygen, while substrate 2 is copper or copper alloy. FIG. 2 shows how the titanium-and-oxygen-containing coating 3 deposited e.g. by ALD evenly conforms to the surface structure of an object 4 having a rough or porous surface, or machined details. In FIG. 3, the coating 6 according to the invention, deposited on substrate 7, has been further coated with a layer 5. Such a layer may, for example, be an ALD-deposited layer containing compounds other than titanium oxide, such as aluminium oxide and silicon oxide.

The surface, which is to be coated according to the invention, should be clean from organic contaminants like grease, as well as from inorganic dust and particulate matter. Cleaning methods known to those skilled in the art may be used, involving e.g. surfactants, acid or basic solutions, or ultrasonic cleaning. FIG. 4 shows a section of a substrate 10, which has been coated with a primer layer 9 before coating with layer 8 according to the invention. Such a layer may, for example, be an ALD-deposited layer containing compounds other than titanium oxide, such as aluminium oxide and silicon oxide.

To grow films by means of the ALD technique, objects the surfaces of which shall act as substrate are placed in a reaction chamber, in which process conditions, including temperature and pressure, are adjusted to meet the requirements of the process chemistry and the substrate materials. Once the substrate reaches a stable temperature and pressure, a first precursor vapor is directed over the substrates. Some of this vapor chemisorbs on the surface, resulting in a one monolayer thick film. In true ALD, the vapor will not attach to itself and this process is therefore self-limiting. A purge gas is introduced to remove any excess of the first vapor and any volatile reaction products. Subsequently, a second precursor vapor is introduced which reacts with the monolayer of the first chemisorbed vapor. Finally the purge gas is introduced again to remove any excess of the second vapor as well as any volatile reaction products. This completes one cycle. This procedure is repeated until the desired film thickness is achieved. A key to true ALD growth is to have the correct precursor vapors alternately pulsed into the reaction chamber. Another prerequisite in the ALD process is that each starting material is available in sufficient concentration for thin film formation over the whole substrate surface area and no extensive precursor decomposition takes place. The flow velocities and precursor concentrations may be optimized for optimal production economy and efficiency. In a process according to the invention, strict adherence to ALD principles may not be necessary. Thus, in a cost-efficient process according to the invention, the purge stages need not be perfect, but a degree of overlap of the precursor pulses (up to 10% of the total material amount) may be allowed, as the bulk (about 90%) of the film nevertheless grows according to ALD principles, and a sufficient degree of conformity and a sufficient lack of defects and pinholes is achieved. Metal leaching is reduced considerably by using a method according to this invention even if coating process does not strictly adhere to the ALD principle, or purge stages are not perfect.

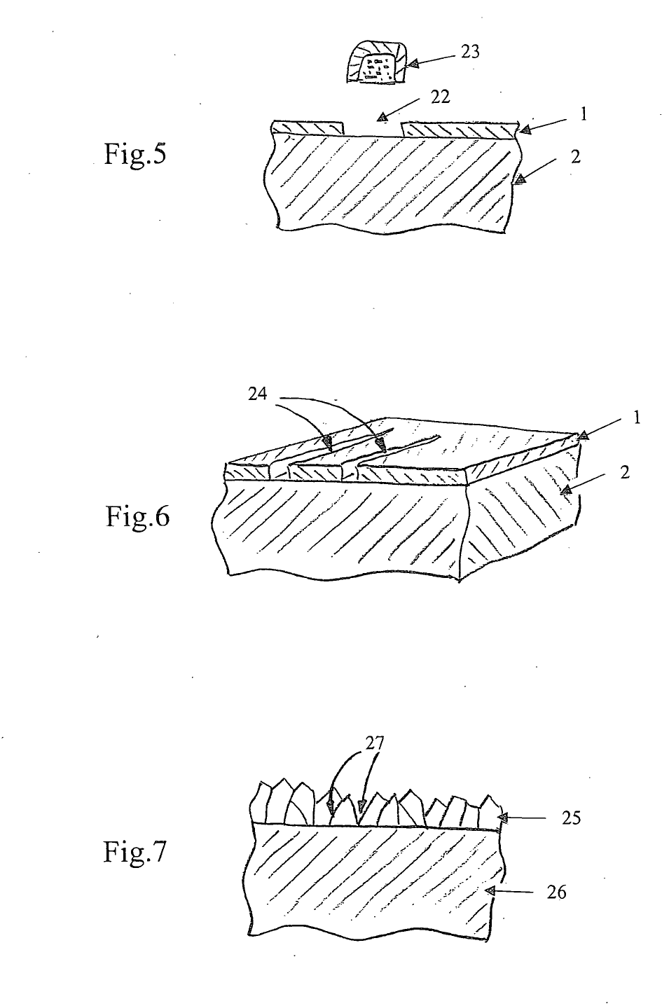

FIGS. 5 to 7 show examples of cases where the film coating does not completely cover the surface. FIG. 5 shows a point defect 22 in a film coating 1, caused by a particle 23 that comes off the surface of substrate 2 after the coating is finished. FIG. 6 shows cracks 24 caused by film stress relaxation in film coating 1. Stresses may occur due to differences in physical properties of substrate 2 and of film coating materials or due to stretching or bending of substrate material. FIG. 7 shows defects 27 which may occur as grain boundaries in the polycrystalline film coating 25 on a substrate 26. Metal leaching is reduced considerably by using at least a partial film according to this invention even if the film coating includes this kind of defects or discontinuities. Partial coverage of the coating may also include cases where a section of the substrate surface is covered essentially without defects, and another section is left without a film coating.

The object selected for coating may be placed in the reaction chamber of a deposition device, or in the alternative the interior of the fitting, which is to be coated, functions as a reaction chamber, whereby the substrate is only the inner surfaces of the fitting. In the latter case, couplings for generating a diminished pressure and for conducting the required reagents into the object are connected to the ends of the fitting, and the coating sequence is carried out inside the fitting affecting the same surfaces that will contact water when the fitting has been installed for use. The substrate temperature may be controlled e.g. by placing the object in an oven.

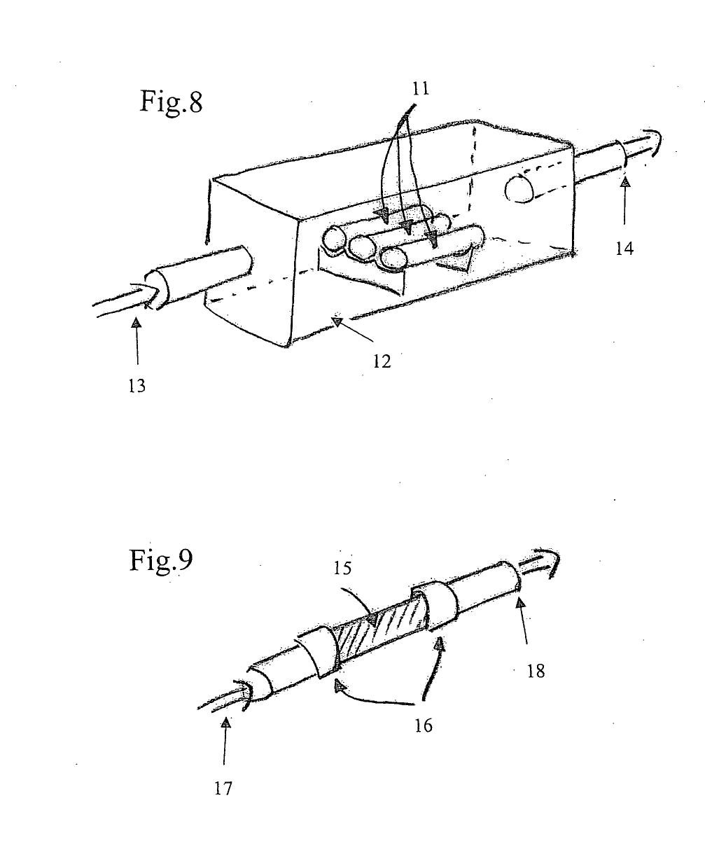

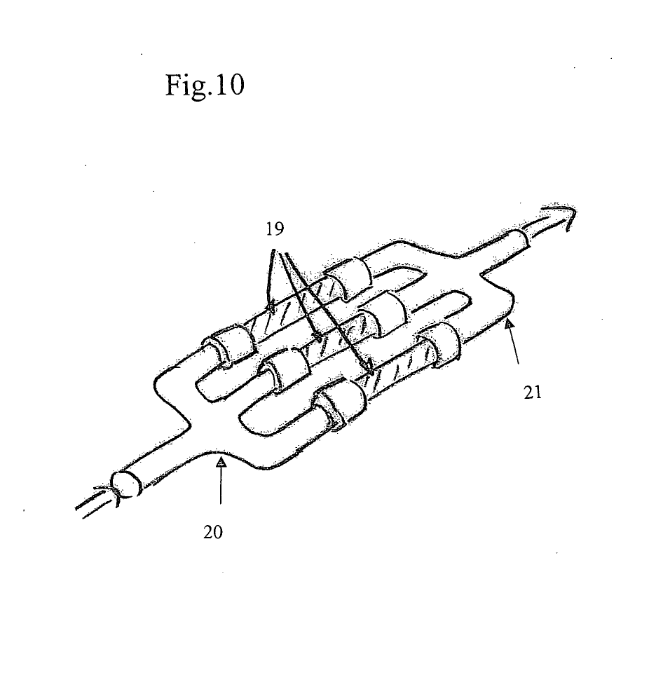

FIG. 8 shows the basic principle of a coating process, e.g. ALD, in which the objects 11 enclosed in chamber 12 are coated on all surfaces. The coating precursors are introduced according to the chosen sequence through inlet 13, and previous chamber atmosphere leaves through outlet 14. For internal-only coating, an arrangement according to FIG. 9 may be used. The hollow object 15 is connected to inlet 17 and outlet 18 by couplings 16, and the sequence is carried out using the object as a chamber. As shown in FIG. 10, several objects 19 may be coated in this manner simultaneously using manifolds 20 and 21, allowing parallel flow through the objects. Further manifolds or couplings (not shown) may be required to allow connection of separate sources for e.g. titanium and oxygen, respectively.

Below, several possible precursors are listed for the deposition of titanium oxide in an ALD process.
Titanium halides, e.g.:
   Titanium (IV) chloride, TiCl₄
   Titanium (IV) bromide, TiBr₄
   Titanium (IV) iodide, TiI₄
Titanium alkoxides, e.g.:
   Titanium (IV) ethoxide, Ti[OC₂H₅]₄
   Titanium (IV) i-propoxide, Ti[OCH(CH₃)₂]₄
   Titanium (IV) t-butoxide, Ti[OC₄H₉]₄
Titanium amides, e.g.:
   Tetrakis(dimethylamino)titanium, Ti[N(CH₃)₂]₄
   Tetrakis(diethylamino)titanium, Ti[N(C₂H₅)₂]₄
   Tetrakis(ethylmethylamino)titanium, Ti[N(C₂H₅)(CH₃)]₄
Titanium acetamidinates

Additionally, several organometallic titanium compounds exist which are suitable as precursors.

Preferably, the titanium and the oxygen originate from separate precursors.

As a titanium source, TiCl₄ is the preferred choice, because of its low cost and availability from several vendors.

Useful precursors for oxygen include water, oxygen, ozone and alcohols. A particularly preferred combination is TiCl₄ and water at a substrate temperature below 150° C. This yields a robust, amorphous layer of good quality. A Cl content of >0.1 percent by weight may provide enhanced protective properties and amorphousness. Examples of useful silicon and aluminium precursors for silicon oxide or for mixtures of silicon oxide and aluminium oxide are tris(tert-butoxy)silanol, tris(tert-pentoxy)silanol, tetrabutoxysilane, tetraethoxysilane, aluminium chloride and trimethylaluminium.

Examples of suitable devices for carrying out the invention are those commercially available from Planar Systems, Inc., e.g. the P400A ALD reactor.

As mentioned above, other possible processes for carrying out the invention include sol-gel processes. These involve subjecting a precursor compound to a series of hydrolysis and polymerisation reactions to form a colloidal suspension or sol. The sol may be deposited on a substrate, and by heat treatment a dense film is formed. Deposition of the sol may be effected by dipping, spraying or spinning.

1. A method for reducing or eliminating the leaching of metal from a metal surface comprising copper into a liquid in contact with said metal surface, wherein the metal surface is coated at least partially with a film including at least one layer comprising titanium and oxygen.

2. A method according to claim 1, wherein more than 30% of said metal surface is coated with a film comprising titanium and oxygen.

3. A method according to claim 1, wherein said metal surface is completely coated with a film comprising titanium and oxygen.

4. A method according to claim 1, wherein said at least one layer comprises titanium oxide.

5. A method according to claim 1, wherein the source of titanium is separate from that of oxygen.

6. A method according to claim 1, wherein the coating process is carried out by Atomic Layer Deposition (ALD).

7. A method according to claim 1, wherein the coating process is carried out using a process selected from the group consisting of Chemical Vapor Deposition (CVD), Metal Organic Vapor Deposition (MOCVD) and sol-gel techniques.

8. A method according to claim 1, wherein the film coating additionally comprises at least one from the group consisting of silicon and aluminium.

9. A method according to claim 1, wherein a primer layer is deposited between the metal surface and the film coating.

10. A method according to claim 1, wherein a protective layer is deposited over the film coating.

11. A method according to claim 1, wherein the coating process is carried out within a conduit in a metal object, said conduit being the same that carries water during the final use of the object.

12. A method according to claim 1, wherein the coating process is carried out simultaneously for at least two metal objects, said at least two metal objects being attached to one or several manifold(s) for allowing parallel flow through the objects.

13. A method according to claim 1, wherein couplings or manifolds are used for connecting separate sources for titanium and oxygen precursors.

14. A method according to claim 1, wherein the thickness of the film coating is less than 10 000 nm.

15. A method according to claim 1, wherein the thickness of the film coating is in the range 3-1000 nm.

16. A method according to claim 1, wherein the thickness of the film coating is in the range 30-100 m.

17. A method according to claim 1, wherein the at least one layer comprising titanium and oxygen comprises >0.1% Cl by weight.

18. A method according to claim 1, wherein the metal surface is that of a plumbing component or an assembly of plumbing components.

19. A method according to claim 2, wherein the metal surface is that of a plumbing component or an assembly of plumbing components.

20. A method according to claim 3, wherein the metal surface is that of a plumbing component or an assembly of plumbing components.
